(19) United States
(12) Patent Application Publication
(10) Pub. No.: US 2025/0204256 A1
(43) Pub. Date: Jun. 19, 2025

(54) THERMOELECTRIC CONVERSION ELEMENT

(71) Applicant: Panasonic Intellectual Property Management Co., Ltd., Osaka (JP)

(72) Inventors: Kouhei TAKAHASHI, Osaka (JP); Masaki FUJIKANE, Osaka (JP); Kunihiko NAKAMURA, Osaka (JP); Atsushi HIMENO, Osaka (JP); Naoki TAMBO, Kyoto (JP); Hiroyuki TANAKA, Nara (JP)

(21) Appl. No.: 19/066,984

(22) Filed: Feb. 28, 2025

Related U.S. Application Data
(63) Continuation of application No. PCT/JP2023/030822, filed on Aug. 25, 2023.

(30) Foreign Application Priority Data
Aug. 31, 2022 (JP) 2022-138384

(51) Int. Cl. H10N 10/857; H10N 10/01; H10N 10/17

(52) U.S. Cl. CPC H10N 10/857; H10N 10/01; H10N 10/17

(57) ABSTRACT

A thermoelectric conversion element includes a thermoelectric member. The thermoelectric member has a phononic crystal including a plurality of holes arranged along a plane. In the thermoelectric conversion element, at least one condition selected from the group consisting of the following (i) and (ii) is satisfied: (i) an area occupied by at least one of the holes in a plan view of at least one of both end surfaces of the thermoelectric member in a direction in which the hole extends is smaller than an average value of cross-sectional areas of the hole; and (ii) at least one of the holes extends separately from at least one of both end surfaces.

This application is a continuation of PCT/JP2023/030822 filed on Aug. 25, 2023, which claims foreign priority of Japanese Patent Application No. 2022-138384 filed on Aug. 31, 2022, the entire contents of both of which are incorporated herein by reference.

### BACKGROUND OF THE INVENTION

### 1. Field of the Invention

The present disclosure relates to a thermoelectric conversion element.

### 2. Description of Related Art

Thermoelectric conversion is a technology of directly converting heat energy to electric energy using the Seebeck effect in which an electromotive force is generated in proportion to a temperature difference applied between both ends of a material. The performance of a thermoelectric conversion element can be evaluated by a performance index Z or a nondimensionalized performance index ZT which is a product of the performance index Z and an absolute temperature T. ZT is described as ZT=S²T/ρ_{K}, using a Seebeck coefficient S, an electrical resistivity ρ, and a thermal conductivity κ of a thermoelectric material in the thermoelectric conversion element. Therefore, in the thermoelectric conversion element, using a thermoelectric material of which the Seebeck coefficient S is high and the electrical resistivity ρ and the thermal conductivity κ are low is desirable in terms of high thermoelectric conversion performance.

For example, WO2020/174764 describes a thermoelectric conversion element including a thin-film-shaped member having a phononic crystal structure. The phononic crystal structure is a two-dimensional phononic crystal structure in which a plurality of through holes are regularly arranged in a cycle of nanometer order of 1 nm to 1000 nm.

US 2015/0015930 A1 describes that a thermal conductivity is reduced in a material having a structure such as a nanophononic crystal. In Nomura et al., “Impeded thermal transport in Si multiscale hierarchical architectures with phononic crystal nanostructures”, Physical Review B 91, 205422 (2015), thermal conduction and phonon transportation in a plane in a single-crystal and polycrystal Si two-dimensional phononic crystal nanostructures are described, and it is described that a multiscale phonon scattering structure efficiently reduces thermal conduction.

### SUMMARY OF THE INVENTION

The above technologies have room for reconsideration in terms of performance improvement of a thermoelectric conversion element. Accordingly, the present disclosure provides a technology that is advantageous in terms of performance improvement of a thermoelectric conversion element.

The present disclosure provides the following thermoelectric conversion element.

A thermoelectric conversion element includes a thermoelectric member having a phononic crystal including a plurality of holes arranged along a plane, wherein
at least one condition selected from the group consisting of the following (i) and (ii) is satisfied:
(i) an area occupied by at least one of the holes in a plan view of at least one of both end surfaces of the thermoelectric member in a direction in which the hole extends is smaller than an average value of cross-sectional areas of the hole; and
(ii) at least one of the holes extends separately from at least one of the both end surfaces.

With the thermoelectric conversion element of the present disclosure, the interfacial thermal resistance at the thermoelectric member is likely to become low, thus providing an advantage in terms of performance improvement of a thermoelectric conversion element.

### BRIEF DESCRIPTION OF THE DRAWINGS

FIG. 1 is a sectional view schematically showing a thermoelectric conversion element of embodiment 1.

FIG. 2A is a plan view showing an example of a unit lattice of a phononic crystal.

FIG. 2B is a plan view showing another example of the unit lattice of the phononic crystal.

FIG. 2C is a plan view showing still another example of the unit lattice of the phononic crystal.

FIG. 2D is a plan view showing still another example of the unit lattice of the phononic crystal.

FIG. 3 is a plan view showing an example of the phononic crystal.

FIG. 4A is a sectional view showing an example of the phononic crystals in a p-type thermoelectric member and an n-type thermoelectric member.

FIG. 4B is a sectional view showing an example of the phononic crystals in a p-type thermoelectric member and an n-type thermoelectric member.

FIG. 5A is a sectional view showing a method for manufacturing the thermoelectric conversion element of embodiment 1.

FIG. 5B is a sectional view showing the method for manufacturing the thermoelectric conversion element of embodiment 1.

FIG. 5C is a sectional view showing the method for manufacturing the thermoelectric conversion element of embodiment 1.

FIG. 5D is a sectional view showing the method for manufacturing the thermoelectric conversion element of embodiment 1.

FIG. 5E is a sectional view showing the method for manufacturing the thermoelectric conversion element of embodiment 1.

FIG. 5F is a sectional view showing the method for manufacturing the thermoelectric conversion element of embodiment 1.

FIG. 5G is a sectional view showing the method for manufacturing the thermoelectric conversion element of embodiment 1.

FIG. 5H is a plan view showing the method for manufacturing the thermoelectric conversion element of embodiment 1.

FIG. 5I is a sectional view showing the method for manufacturing the thermoelectric conversion element of embodiment 1.

FIG. 5J is a sectional view showing the method for manufacturing the thermoelectric conversion element of embodiment 1.

FIG. 5K is a plan view showing the method for manufacturing the thermoelectric conversion element of embodiment 1.

FIG. 5L is a sectional view showing the method for manufacturing the thermoelectric conversion element of embodiment 1.

FIG. 5M is a sectional view showing the method for manufacturing the thermoelectric conversion element of embodiment 1.

FIG. 5N is a sectional view showing the method for manufacturing the thermoelectric conversion element of embodiment 1.

FIG. 6 is a sectional view schematically showing a thermoelectric conversion element of embodiment 2.

FIG. 7A is a sectional view showing a method for manufacturing the thermoelectric conversion element of embodiment 2.

FIG. 7B is a sectional view showing the method for manufacturing the thermoelectric conversion element of embodiment 2.

FIG. 7C is a sectional view showing the method for manufacturing the thermoelectric conversion element of embodiment 2.

FIG. 7D is a sectional view showing the method for manufacturing the thermoelectric conversion element of embodiment 2.

FIG. 7E is a sectional view showing the method for manufacturing the thermoelectric conversion element of embodiment 2.

FIG. 8 is a sectional view schematically showing a thermoelectric conversion element of embodiment 3.

FIG. 9 is a sectional view showing a method for manufacturing the thermoelectric conversion element of embodiment 3.

FIG. 10 is a sectional view schematically showing a thermoelectric conversion element of embodiment 4.

FIG. 11A is a sectional view showing a method for manufacturing the thermoelectric conversion element of embodiment 4.

FIG. 11B is a sectional view showing the method for manufacturing the thermoelectric conversion element of embodiment 4.

FIG. 11C is a sectional view showing the method for manufacturing the thermoelectric conversion element of embodiment 4.

FIG. 11D is a sectional view showing the method for manufacturing the thermoelectric conversion element of embodiment 4.

FIG. 11E is a sectional view showing the method for manufacturing the thermoelectric conversion element of embodiment 4.

FIG. 11F is a sectional view showing the method for manufacturing the thermoelectric conversion element of embodiment 4.

FIG. 11G is a sectional view showing the method for manufacturing the thermoelectric conversion element of embodiment 4.

FIG. 12 is a sectional view showing another example of the thermoelectric member.

### DETAILED DESCRIPTION

(Finding on which the Present Disclosure is Based)

The performance of a thermoelectric conversion element can depend on also factors other than a physical property of a thermoelectric material. For example, it is conceivable to configure a thermoelectric conversion element so as to have a laminated structure in which a substrate, a metal wiring layer, a thermoelectric material, a metal wiring layer, and a substrate are arranged in this order along the direction of heat flow. In this case, an effective thermal resistance R_{eff} of a thermoelectric member for which the influence of the interfaces between the thermoelectric member and members such as the metal wiring layers in contact with the thermoelectric material is considered is represented as R_{eff}=R_{TH}+R_{U}+R_{B}. Here, R_{TH} is the thermal resistance of the thermoelectric member, R_{U} is the interfacial thermal resistance at one end surface of the thermoelectric member, and R_{B} is the interfacial thermal resistance at another end surface of the thermoelectric member. As the thermal resistance R_{eff} becomes closer to the thermal resistance R_{TH}, the thermoelectric conversion element can exhibit higher performance. In other words, as the interfacial thermal resistances at the thermoelectric member become smaller, the thermoelectric conversion element is expected to exhibit higher performance.

In particular, in a case where the thermoelectric member has a thin-film shape in the thermoelectric conversion element, contribution of the interfacial thermal resistance in the effective thermal resistance of the thermoelectric member is likely to become great. Therefore, in order to enhance the performance of the thermoelectric conversion element, it is important to reduce the interfacial thermal resistances between the thermoelectric member and other members such as the metal wiring layers, as much as possible.

Accordingly, the present inventors have studied intensively on a technology with which the interfacial thermal resistances between the thermoelectric member and other members are likely to become low and which is advantageous in terms of performance improvement of the thermoelectric conversion element, and thus have finally completed the thermoelectric conversion element of the present disclosure.

The present disclosure provides the following thermoelectric conversion element.

A thermoelectric conversion element includes a thermoelectric member having a phononic crystal including a plurality of holes arranged along a plane, wherein
at least one condition selected from the group consisting of the following (i) and (ii) is satisfied:
(i) an area occupied by at least one of the holes in a plan view of at least one of both end surfaces of the thermoelectric member in a direction in which the hole extends is smaller than an average value of cross-sectional areas of the hole; and
(ii) at least one of the holes extends separately from at least one of the both end surfaces.

In the above thermoelectric conversion element, the interfacial thermal resistances at the thermoelectric member are likely to become low, thus providing an advantage in terms of performance improvement of the thermoelectric conversion element.

### Embodiments of the Present Disclosure

Hereinafter, embodiments of the present disclosure will be described with reference to the drawings. The embodiments described below are all comprehensive or specific examples. The numerical values, shapes, materials, components, arrangement positions of the components, connection forms, process conditions, steps, order of the steps, etc., shown in the following embodiments are examples, and are not intended to limit the present disclosure. In addition, among the components in the following embodiments, the components that are not described in the independent claims that represent broadest concepts are described as discretionary components. Each drawing is a schematic diagram, and is not necessarily exactly illustrated.

### Embodiment 1

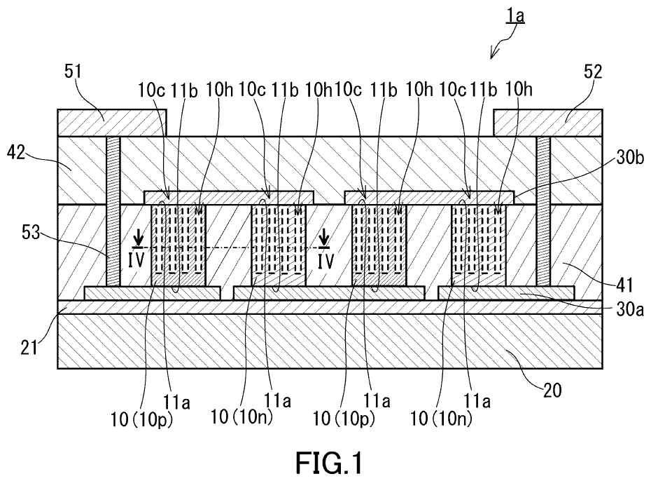

FIG. 1 is a sectional view schematically showing a thermoelectric conversion element of embodiment 1. A thermoelectric conversion element 1a includes thermoelectric members 10. Each thermoelectric member 10 has a phononic crystal 10c including a plurality of holes 10h arranged along a plane. In the thermoelectric conversion element 1a, at least one condition selected from the group consisting of the following (i) and (ii) is satisfied:
(i) an area occupied by at least one of the holes 10h in a plan view of at least one of both end surfaces 11a and 11b of the thermoelectric member 10 in the direction in which the hole 10h extends is smaller than an average value of cross-sectional areas of the hole 10h; and
(ii) at least one of the holes 10h extends separately from at least one of both end surfaces 11a and 11b.

As shown in FIG. 1, the thermoelectric conversion element 1a further includes a substrate 20. The thermoelectric member 10 is disposed above the substrate 20. The thermoelectric member 10 has a first end surface 11a, and a second end surface 11b which is closer to the substrate 20 than the first end surface 11a is, in the direction in which the hole 10h extends.

In the thermoelectric conversion element 1a, the effective thermal resistance R_{eff} of the thermoelectric member 10 is represented as R_{eff}=R_{TH}+R_{U}+R_{B}, as described above. The interfacial thermal resistance R_{U} can be represented as R_{U}=(A_{U2}*h_{U})−1. Here, A_{U2} is the area of the first end surface 11a of the thermoelectric member 10 after the phononic crystal 10c is formed, and h_{U} is a heat transfer coefficient at the first end surface 11a of the thermoelectric member 10. The interfacial thermal resistance R_{B} can be represented as R_{B}=(A_{B2}*h_{B})⁻¹. Here, A_{B2} is the area of the second end surface 11b of the thermoelectric member 10 after the phononic crystal 10c is formed, and h_{B} is a heat transfer coefficient at the second end surface 11b of the thermoelectric member 10. The area A_{U2} and the area A_{B2} can be represented as A_{U2}=A_{U1}*(1−ϕ_{U}) and A_{B2}=A_{B1}*(1−ϕ_{B}), respectively. Here, A_{U1} is the area of an end surface corresponding to the first end surface 11a of the thermoelectric member 10 before the phononic crystal 10c is formed. ϕ_{U} is the ratio of the area of openings, in contact with the first end surface 11a, of the holes 10h forming the phononic crystal 10c to the sum of the area of the openings and the area of the first end surface 11a. A_{B1} is the area of an end surface corresponding to the second end surface 11b of the thermoelectric member 10 before the phononic crystal 10c is formed. ϕ_{B} is the ratio of the area of openings, in contact with the second end surface 11b, of the holes 10h forming the phononic crystal 10c to the sum of the area of the openings and the area of the second end surface 11b. The above formula regarding the thermal resistance R_{eff} can be rewritten as R_{eff}=R_{TH}+ {A_{U1}*(1−ϕ_{U})*h_{U}}⁻¹+{A_{B1}*(1−ϕ_{B})*h_{B}}⁻¹. From this formula, it is understood that reducing the opening ratio on at least one end surface side selected from the group consisting of the first end surface 11a side and the second end surface 11b side of the thermoelectric member 10 is advantageous in terms of reduction in the interfacial thermal resistances R_{U} and R_{B}.

As described above, in the thermoelectric conversion element 1a, at least one condition selected from the group consisting of the above (i) and (ii) is satisfied. Thus, the opening ratio on at least one end surface side selected from the group consisting of the first end surface 11a side and the second end surface 11b side of the thermoelectric member 10 is likely to become small. As a result, the interfacial thermal resistance at the thermoelectric member 10 is likely to become low, so that the performance of the thermoelectric conversion element is likely to become high.

Regarding the condition (i), an average value of cross-sectional areas of the hole 10h can be determined by dividing the volume of the inside of the hole 10h by a length which is the dimension of the hole 10h in the direction in which the hole 10h extends, for example. Whether or not a specific hole 10h satisfies the condition (i) may be determined by observing a longitudinal section of the hole 10h. For example, in the longitudinal section of the hole 10h, if the hole 10h is tapered toward at least one of both end surfaces 11a and 11b of the thermoelectric member 10, it can be determined that the hole 10h satisfies the condition (i).

As shown in FIG. 1, in the thermoelectric member 10, at least one of the holes 10h extends separately from the second end surface 11b, for example. In other words, in the thermoelectric member 10, an end on the second end surface 11b side of at least one of the holes 10h is closed. With this configuration, the ratio of the area of the openings, in contact with the second end surface 11b, of the holes 10h forming the phononic crystal 10c to the sum of the area of the openings and the area of the second end surface 11b is likely to become small. Thus, the interfacial thermal resistance R_{B} is likely to become low, so that the performance of the thermoelectric conversion element 1a is likely to become high.

Among the holes 10h of the thermoelectric member 10, the number of the holes 10h extending separately from the second end surface 11b is not limited to a specific value. For example, 25% or more of the holes 10h of the thermoelectric member 10 on a number basis extend separately from the second end surface 11b. In the thermoelectric member 10, the ratio of the number of the holes 10h extending separately from the second end surface 11b to the number of the holes 10h of the thermoelectric member 10 may be 30% or more, 40% or more, 50% or more, or 60% or more. This ratio may be 70% or more, 80% or more, or 90% or more. In the thermoelectric member 10, all the holes 10h may extend separately from the second end surface 11b.

For example, in a case where all the holes 10h of the thermoelectric member 10 extend separately from the second end surface 11b, the interfacial thermal resistance R_{B} can be halved as compared to a thermoelectric conversion element according to a reference example. The thermoelectric conversion element according to the reference example is configured to have the same structure except that the thermoelectric member 10 has a phononic crystal in which the holes 10h are formed as through holes so that ϕ_{B} becomes 0.5.

In a case where the ratio of the number of the holes 10h extending separately from the second end surface 11b to the number of the holes 10h of the thermoelectric member 10 is 50%, the interfacial thermal resistance R_{B} can be reduced to about 0.67 times as compared to the thermoelectric conversion element according to the reference example. In a case where the ratio of the number of the holes 10h extending separately from the second end surface 11b to the number of the holes 10h of the thermoelectric member 10 is 25%, the interfacial thermal resistance R_{B} can be reduced to about 0.8 times as compared to the thermoelectric conversion element according to the reference example.

In a case where the hole 10h extends separately from the second end surface 11b, the ratio of a distance between the second end surface 11b and the hole 10h in the direction in which the hole 10h extends to the dimension of the thermoelectric member 10 in the direction in which the hole 10h extends, is not limited to a specific value. The ratio is 20% or less, for example. With this configuration, the thermal conductivity of the thermoelectric member 10 is likely to become low. This is because the thermal conductivity of the thermoelectric member 10 is expected to be reduced owing to the phononic crystal 10c in an area where the hole 10h is present in the direction in which the hole 10h extends in the thermoelectric member 10. Thus, reducing the above ratio is advantageous in terms of reduction in the thermal conductivity of the thermoelectric member 10. The above ratio may be 15% or less, 10% or less, or 5% or less.

As shown in FIG. 1, for example, in the thermoelectric member 10, ends on the first end surface 11a side of the holes 10h are opened.

In the phononic crystal 10c, the shapes of the holes 10h are not limited to specific shapes. In a plan view of the first end surface 11a, each hole 10h may have a circular shape, or a polygonal shape such as a triangular shape or a quadrangular shape.

The holes 10h in the phononic crystal 10c are formed in cyclic arrangement, for example. For example, in a plan view of the phononic crystal 10c, the holes 10h are regularly arranged. The cycle of arrangement of the holes 10h is 1 nm to 5 μm, for example. The wavelength of a phonon which carries heat mainly ranges from 1 nm to 5 μm. Thus, setting the cycle of arrangement of the holes 10h at 1 nm to 5 μm is advantageous for reducing the thermal conductivity of the thermoelectric member 10 having the phononic crystal 10c.

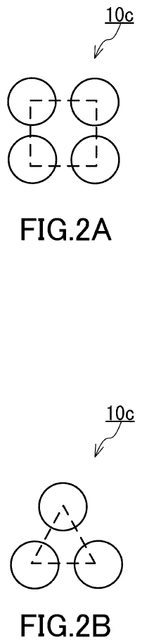

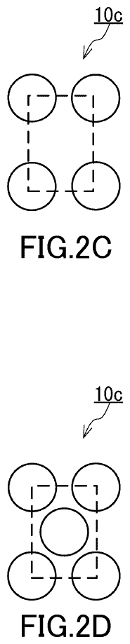

The unit lattice of the phononic crystal 10c is not limited to a specific unit lattice. FIG. 2A, FIG. 2B, FIG. 2C, and FIG. 2D show examples of the unit lattice of the phononic crystal 10c. As shown in FIG. 2A, the unit lattice of the phononic crystal 10c may be a square lattice. As shown in FIG. 2B, the unit lattice of the phononic crystal 10c may be a triangular lattice. As shown in FIG. 2C, the unit lattice of the phononic crystal 10c may be a rectangular lattice. As shown in FIG. 2D, the unit lattice of the phononic crystal 10c may be a centered rectangular lattice.

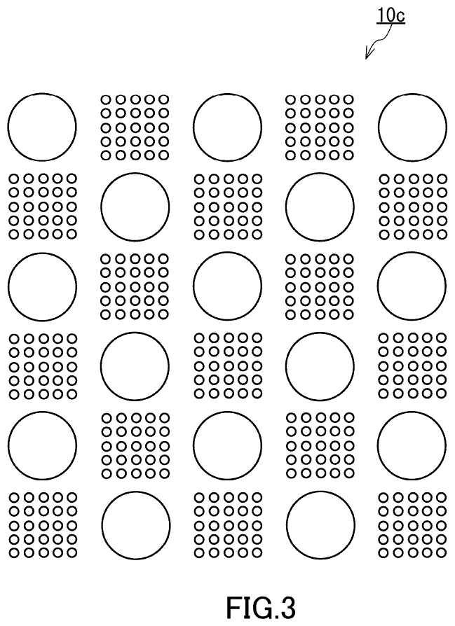

The phononic crystal 10c may include different kinds of unit lattices. FIG. 3 shows another example of the phononic crystal 10c. As shown in FIG. 3, the phononic crystal 10c may have mixed arrangement patterns of the holes 10h having different two kinds of unit lattices, for example.

The phononic crystal 10c is a single crystal formed of one domain, for example. The phononic crystal 10c may be a polycrystal formed of domains of a plurality of phononic crystals 10c. In this case, the phononic crystal 10c has a plurality of domains, and the phononic crystal 10c in each domain is a single crystal. In other words, the phononic crystal 10c in a polycrystal state is a complex of a plurality of phononic single crystals. In the domains, the holes 10h are regularly arranged in different directions. In each domain, the orientations of unit lattices are the same. In a case where the phononic crystal 10c is a polycrystal, the shape of each domain in a plan view is not limited to a specific shape. Examples of the shape of each domain in a plan view are polygonal shapes such as a triangular shape, a square shape, and a rectangular shape, a circular shape, an elliptic shape, and a combined shape thereof. The shape of each domain in a plan view may be an undefined shape. The number of domains included in the phononic crystal 10c is not limited to a specific value.

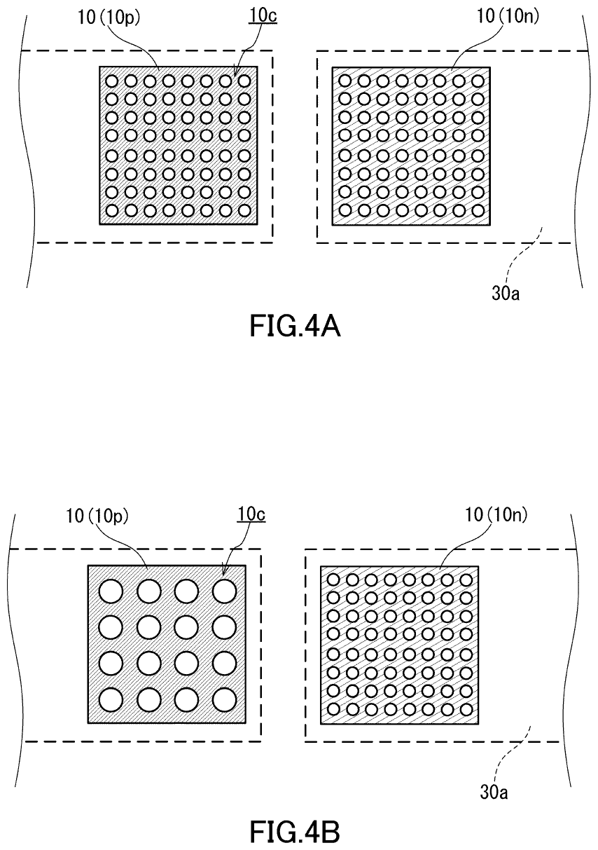

As shown in FIG. 1, the thermoelectric conversion element 1a has p-type thermoelectric members 10p and n-type thermoelectric members 10n, as the thermoelectric members 10, for example. FIG. 4A is a sectional view showing an example of the phononic crystals 10c in the p-type thermoelectric member 10p and the n-type thermoelectric member 10n. FIG. 4A is a sectional view taken along line IV-IV in FIG. 1. As shown in FIG. 4A, for example, the p-type thermoelectric member 10p and the n-type thermoelectric member 10n have the phononic crystals 10c that are the same in structural features such as the arrangement, the cycle, and the diameter of the holes 10h. FIG. 4B is a sectional view showing another example of the phononic crystals 10c in the p-type thermoelectric member 10p and the n-type thermoelectric member 10n. As shown in FIG. 4B, the p-type thermoelectric member 10p and the n-type thermoelectric member 10p may respectively have a first phononic crystal 10c and a second phononic crystal 10c that are different in structural features such as the arrangement, the cycle, and the diameter of the holes 10h.

As shown in FIG. 1, the thermoelectric conversion element 1a further includes a foundation insulation film 21, a first wiring 30a, a second wiring 30b, a first interlayer insulation film 41, a second interlayer insulation film 42, a first electrode pad 51, a second electrode pad 52, and plugs 53, for example.

The foundation insulation film 21 is disposed on the substrate 20. On the foundation insulation film 21, the p-type thermoelectric members 10p and the n-type thermoelectric members 10n are disposed between the first wiring 30a and the second wiring 30b. Each p-type thermoelectric member 10p includes a thermoelectric material having a positive Seebeck coefficient, for example. Each n-type thermoelectric member 16 includes a thermoelectric material as a negative Seebeck coefficient, for example. The p-type thermoelectric members 10p and the n-type thermoelectric members 10n are connected electrically in series via the first wiring 30a and the second wiring 30b, and thus serve as thermocouples. In a case where the thermoelectric conversion element 1a includes a plurality of p-type thermoelectric members 10p and a plurality of n-type thermoelectric members 10n, each p-type thermoelectric member 10p and each n-type thermoelectric member 10n are alternately connected via the first wiring 30a and the second wiring 30b. The p-type thermoelectric members 10p, the n-type thermoelectric members 10n, the first wiring 30a, and the second wiring 30b are covered by the first interlayer insulation film 41 and the second interlayer insulation film 42. The plugs 53 extend through the first interlayer insulation film 41 and the second interlayer insulation film 42. The first electrode pad 51 and the second electrode pad 52 are disposed on the second interlayer insulation film 42. The first electrode pad 51 and the second electrode pad 52 are electrically connected via the plugs 53, the first wiring 30a, the p-type thermoelectric members 10p, the second wiring 30b, and the n-type thermoelectric members 10n.

The substrate 20 is not limited to a specific substrate. The substrate 20 is an Si substrate, for example. The substrate 20 may be a substrate formed by a semiconductor other than Si or a material other than a semiconductor.

The foundation insulation film 21 is not limited to a specific film. The foundation insulation film 21 may contain an oxide insulator such as silicon oxide and aluminum oxide, or a nitride insulator such as silicon nitride and aluminum nitride. In a case where the substrate 20 has an electric insulation property, the foundation insulation film 21 may be omitted. The thickness of the foundation insulation film 21 is not limited to a specific value. The thickness may be 50 nm or greater and 150 μm or smaller, for example.

Materials forming the first wiring 30a and the second wiring 30b are not limited to specific materials as long as the materials have a predetermined electric conductivity. Each of the first wiring 30a and the second wiring 30b contains an impurity semiconductor, metal, or a metal compound, for example. The metal and a metal compound may be a material, such as Al, Cu, TiN, and TaN, used in a general semiconductor process, for example. Each of the first wiring 30a and the second wiring 30b has a thickness of 100 nm to 1 μm, for example.

Desirably, the thermoelectric materials contained in the p-type thermoelectric member 10p and the n-type thermoelectric member 10n are semiconductor materials in which carriers serving for electric conduction can be adjusted to either holes or electrons by doping. Examples of such semiconductor materials are Si, SiGe, SiC, GaAs, InAs, InSb, InP, GaN, ZnO, and BiTe. The semiconductor material is not limited to these examples. The thermoelectric materials contained in the p-type thermoelectric member 10p and the n-type thermoelectric member 10n may be a single-crystal material, a polycrystal material, or an amorphous material. Base materials for the thermoelectric materials of the p-type thermoelectric member 10p and the n-type thermoelectric member 10n may be the same material or different materials. The p-type thermoelectric member 10p and the n-type thermoelectric member 10n have thin-film shapes, for example, and have thicknesses of 100 nm or greater and 10 μm or smaller, for example. In the p-type thermoelectric member 10p and the n-type thermoelectric member 10n, the holes 10h of the phononic crystals 10c extend in the thickness directions of the p-type thermoelectric member 10p and the n-type thermoelectric member 10n.

Materials forming the first interlayer insulation film 41 and the second interlayer insulation film 42 are not limited to specific materials. The first interlayer insulation film 41 and the second interlayer insulation film 42 may contain an oxide insulator such as silicon oxide and aluminum oxide, or a nitride insulator such as silicon nitride and aluminum nitride, for example. Materials forming the first interlayer insulation film 41 and the second interlayer insulation film 42 may be a single-crystal material, a polycrystal material, or an amorphous material. The first interlayer insulation film 41 and the second interlayer insulation film 42 may contain the same material or different materials. The thickness of the first interlayer insulation film 41 corresponds to the thicknesses of the p-type thermoelectric member 10p and the n-type thermoelectric member 10n, for example, and is not limited to a specific value. The thickness of the first interlayer insulation film 41 is 100 nm or greater and 10 μm or smaller, for example. The thickness of the second interlayer insulation film 42 is not limited to a specific value. As shown in FIG. 1, the second interlayer insulation film 42 covers the second wiring 30b. The second interlayer insulation film 42 has a thickness of 100 nm to 2 μm, for example.

Materials forming the first electrode pad 51, the second electrode pad 52, and the plugs 53 are not limited to specific materials. Each of the first electrode pad 51, the second electrode pad 52, and the plugs 53 contains metal or a metal compound, for example. The metal and a metal compound may be materials, such as Al, Cu, TiN, and TaN, used in a general semiconductor process, for example.

In the thermoelectric conversion element 1a, when a temperature difference arises between a top surface of the second interlayer insulation film 42 and a bottom surface of the substrate 20, an electromotive force is generated between the first electrode pad 51 and the second electrode pad 52 by the Seebeck effect. Through the conductive wires connected to the first electrode pad 51 and the second electrode pad 52, the electromotive force is extracted. Thus, the thermoelectric conversion element 1a can be used as an electric generation device or a heat flow sensor.

On the other hand, in the thermoelectric conversion element 1a, when a voltage is applied through the conductive wires connected to the first electrode pad 51 and the second electrode pad 52 so that a current is generated, heat absorption and heat release occur at the top surface of the second interlayer insulation film 42 and the bottom surface of the substrate 20 by the Peltier effect. At which of the top surface of the second interlayer insulation film 42 and the bottom surface of the substrate 20 heat absorption or heat release occurs can change depending on the direction of the current generated with voltage application. Thus, the thermoelectric conversion element 1a can be used as a temperature control device for the purpose of cooling, heating, or the like.

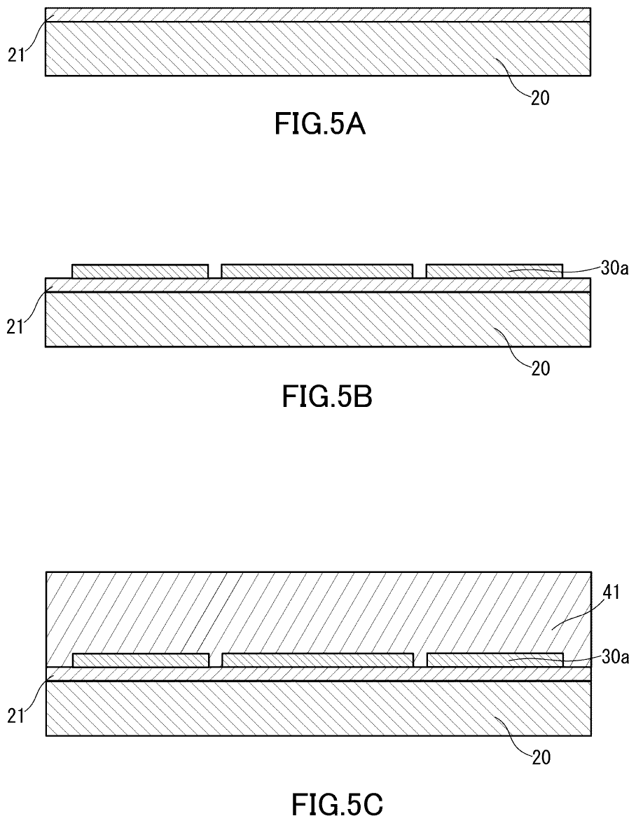

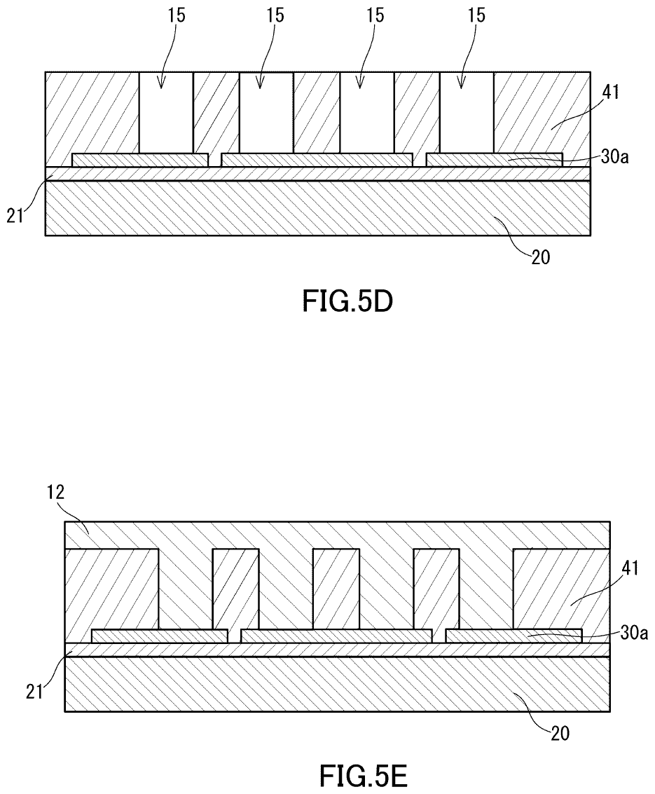

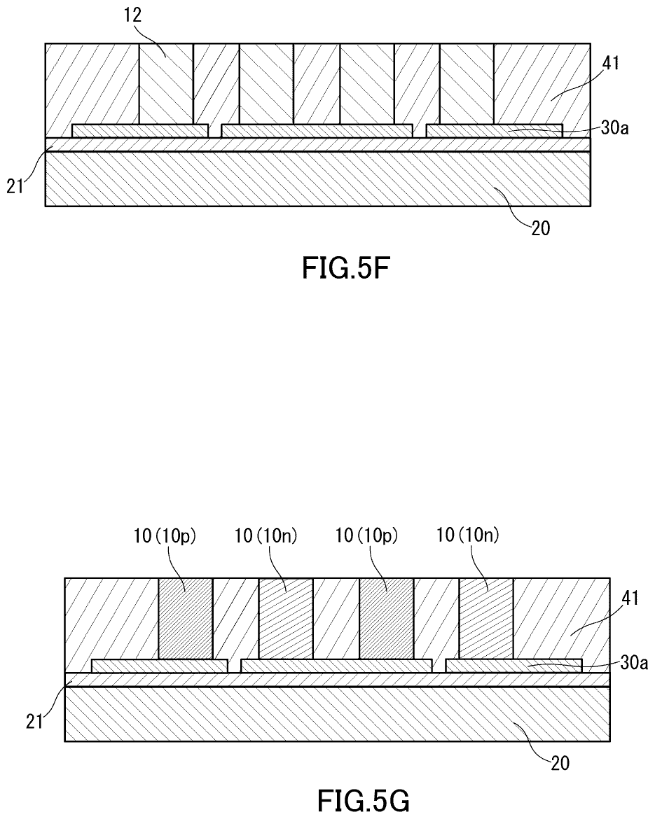

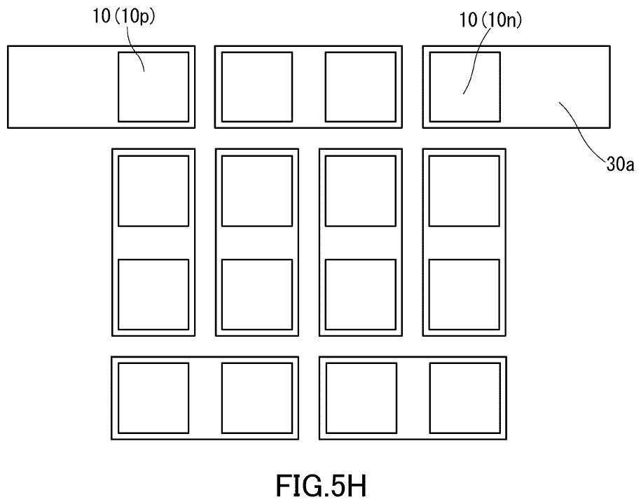

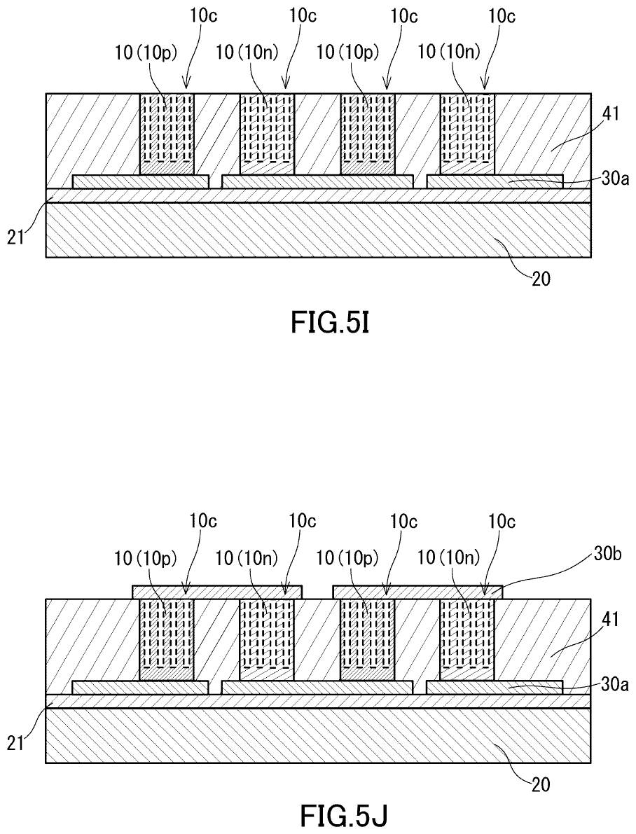

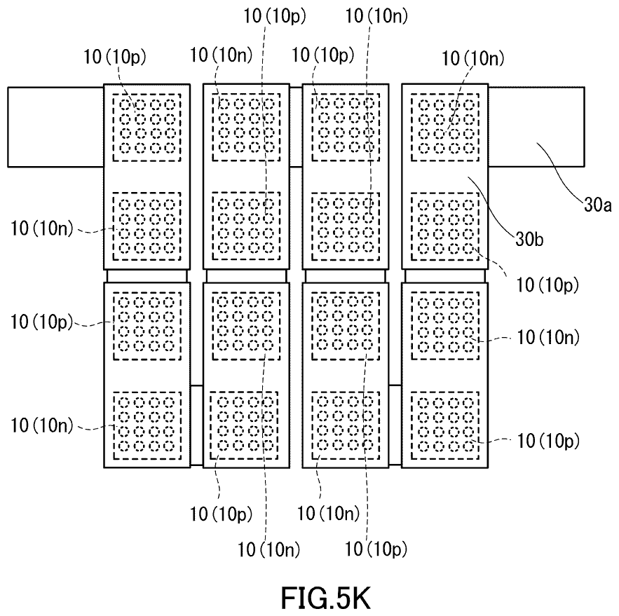

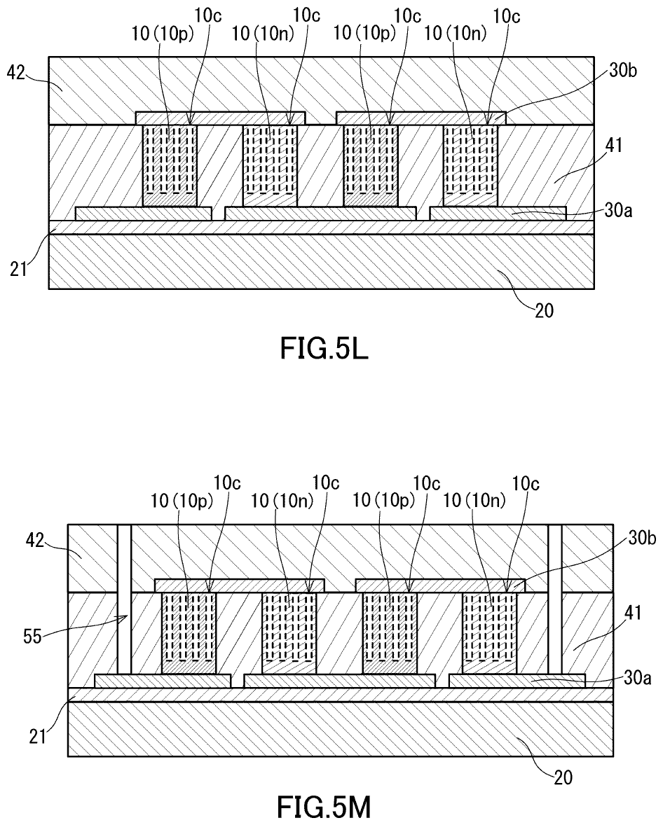

An example of a method for manufacturing the thermoelectric conversion element 1a will be described. The method for manufacturing the thermoelectric conversion element is not limited to the following method. FIG. 5A to FIG. 5N show the method for manufacturing the thermoelectric conversion element 1a of embodiment 1.

As shown in FIG. 5A, the foundation insulation film 21 made of an insulator such as SiO2 is formed on one principal surface of the substrate 20 by sputtering or chemical vapor deposition (CVD). The substrate 20 is an Si substrate, for example.

Next, as shown in FIG. 5B, the first wiring 30a made of an electric conductor such as Al is formed. As the first wiring 30a, a pattern to be the first wiring 30a is formed by photolithography and etching, or lift-off, from an Al film formed by a method such as sputtering.

As shown in FIG. 5C, the first interlayer insulation film 41 is formed so as to cover the first wiring 30a. Next, as shown in FIG. 5D, recesses 15 for forming the thermoelectric members 10 are formed in the first interlayer insulation film 41 by photolithography and etching. For example, bottom surfaces of the recesses 15 are formed by the first wiring 30a.

Next, as shown in FIG. 5E, the thermoelectric material thin film 12 is formed by a method such as sputtering or CVD, so as to fill the recesses 15. The thermoelectric material thin film 12 includes a semiconductor such as polycrystal Si, for example. Next, as shown in FIG. 5F, the thermoelectric material thin film 12 present outside the recesses 15 is removed by a method such as chemical mechanical polishing (CMP). Next, as shown in FIG. 5G, doping is performed in predetermined areas of the thermoelectric material thin film 12, whereby the p-type thermoelectric members 10p and the n-type thermoelectric members 10n are obtained. For the doping, a method such as ion implantation is used. FIG. 5H is a plan view showing an example of arrangement that the p-type thermoelectric members 10p, the n-type thermoelectric members 10n, and the first wiring 30a can have at this stage. In FIG. 5H, the first interlayer insulation film 41 is not shown.

Next, as shown in FIG. 5I, the phononic crystals 10c are formed in the p-type thermoelectric members 10p and the n-type thermoelectric members 10n. For formation of the phononic crystals 10c, a plurality of lithography techniques can be used in accordance with the shapes of the holes 10h. For example, in a case where the phononic crystal 10c has a cycle of 300 nm or greater, photolithography is used. In a case where the phononic crystal 10c has a cycle of 100 nm to 300 nm, electron beam lithography is used. In a case where the phononic crystal 10c has a cycle of 1 nm to 100 nm, block copolymer lithography is used. The method for forming the holes 10h of the phononic crystal 10c is not limited to the above methods. The phononic crystal 10c may be formed using another lithography such as nanoimprint lithography. Whichever lithography is used, the phononic crystals 10c can be formed in the p-type thermoelectric members 10p and the n-type thermoelectric members 10n.

For example, as shown in FIG. 3, the phononic crystal 10c can include a plurality kinds of unit lattices. In this case, the phononic crystal 10c can be formed by creating drawing patterns corresponding to the kinds of unit lattices by photolithography or electron beam lithography in advance. The phononic crystal 10c including the kinds of unit lattices may be formed by combining a plurality of kinds of lithography. For example, a unit lattice having a small cycle is formed in a desired area by block copolymer lithography or electron beam lithography. Then, a unit lattice having a great cycle is formed in an overlapping manner in the same area by photolithography.

In a case where the phononic crystals 10c are formed by photolithography, a photomask with a plurality of holes designed is prepared. Through a process of exposure and development, a pattern of the phononic crystals 10c drawn on the photomask is transferred onto a resist film applied on the p-type thermoelectric member 10p and the n-type thermoelectric member 10n. Then, the p-type thermoelectric member 10p and the n-type thermoelectric member 10n are etched from an upper surface of the resist film, so that the holes 10h in the phononic crystals 10c are formed. Finally, the resist film is removed, whereby the holes 10h in the phononic crystals 10c are obtained.

A case where the phononic crystals 10c are formed by electron beam lithography will be described. In an area for forming the phononic crystals 10c, a drawing pattern of a plurality of holes is inputted to an electron beam irradiation device. Scanning with an electron beam is performed in accordance with the inputted data, to irradiate the p-type thermoelectric member 10p and the n-type thermoelectric member 10n. Thus, a pattern of the phononic crystals 10c is directly drawn on the resist film applied on the p-type thermoelectric member 10p and the n-type thermoelectric member 10n. After the drawn pattern is developed, the p-type thermoelectric member 10p and the n-type thermoelectric member 10n are etched from an upper surface of the resist film on which the pattern has been transferred. Thus, the holes 10h in the phononic crystals 10c are formed. Finally, the resist film is removed, whereby the holes 10h in the phononic crystals 10c are obtained.

In a case where the phononic crystals 10c are formed by block copolymer lithography, a known process condition can be applied. After block copolymer lithography is performed, the holes 10h in the phononic crystals 10c are obtained by etching.

As shown in FIG. 5I, in the p-type thermoelectric members 10p and the n-type thermoelectric members 10n, the holes 10h extend separately from the second end surfaces 11b that are in contact with the first wiring 30a. The etching rates for the thermoelectric materials of the p-type thermoelectric member 10p and the n-type thermoelectric member 10n may be measured in advance and the time for etching may be adjusted, whereby the distances between the second end surfaces 11b and the holes 10h can be adjusted into a desired range.

Next, as shown in FIG. 5J, the second wiring 30b made of an electric conductor such as Al is formed. For example, a pattern to be the second wiring 30b is formed by photolithography and etching, or lift-off, from an Al film formed by sputtering or the like. In order to prevent a material forming the second wiring 30b from entering the insides of the holes 10h of the phononic crystal 10c, a method such as oblique incidence sputtering may be used. FIG. 5K is a plan view showing an example of arrangement that the p-type thermoelectric members 10p, the n-type thermoelectric members 10n, the first wiring 30a, and the second wiring 30b can have at this stage. In FIG. 5K, the first interlayer insulation film 41 is not shown. As shown in FIG. 5K, thermocouples with the p-type thermoelectric members 10p and the n-type thermoelectric members 10n connected electrically in series are formed.

Next, as shown in FIG. 5L, the second interlayer insulation film 42 is formed so as to cover the second wiring 30b. Thereafter, as shown in FIG. 5M, contact holes 55 are formed by photolithography and etching so as to extend through the first interlayer insulation film 41 and the second interlayer insulation film 42. At this stage, parts of surfaces of the first wiring 30a in contact with the first interlayer insulation film 41 are exposed through the contact holes 55. Next, a thin film of a metal material such as Al or TiN is formed by a method such as sputtering or CVD, so as to fill the contact holes 55. Then, as shown in FIG. 5N, the thin film of the metal material outside the contact holes 55 is removed by a method such as CMP, whereby the plugs 53 are obtained. Finally, a metal thin film containing a material such as Al is formed on the second interlayer insulation film 42 and the plugs 53. The metal thin film is etched, whereby the first electrode pad 51 and the second electrode pad 52 are obtained. Thus, the thermoelectric conversion element 1a can be manufactured.

### Embodiment 2

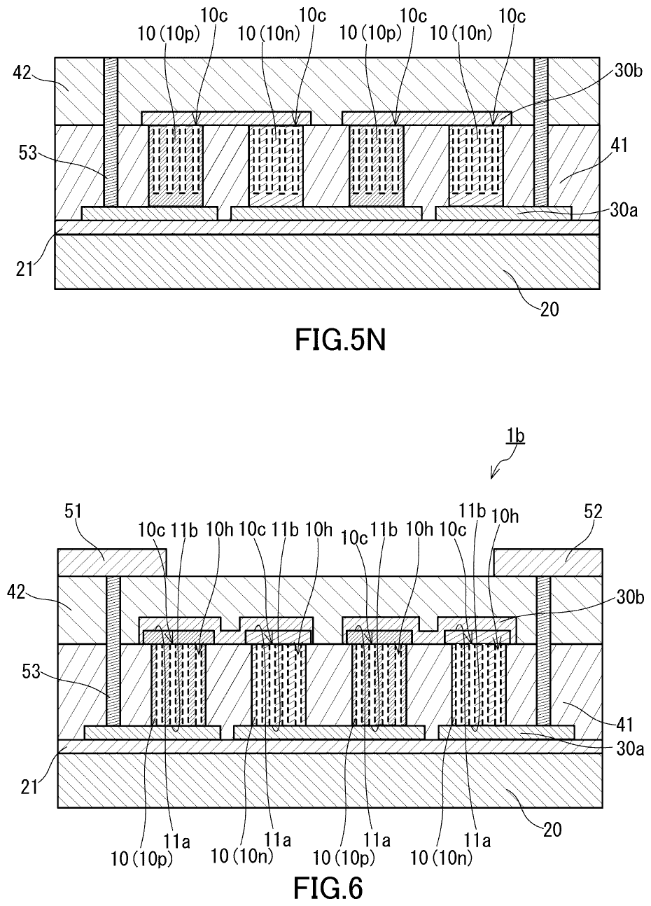

FIG. 6 shows a thermoelectric conversion element 1b of embodiment 2. The thermoelectric conversion element 1b is configured in the same manner as the thermoelectric conversion element 1a, except for specifically described parts. Components of the thermoelectric conversion element 1b that are the same as or correspond to those of the thermoelectric conversion element 1a are denoted by the same reference characters and the detailed description thereof is omitted. The description regarding the thermoelectric conversion element 1a also applies to the thermoelectric conversion element 1b, unless there is technical contradiction therebetween.

As shown in FIG. 6, in the thermoelectric member 10 of the thermoelectric conversion element 1b, at least one of the holes 10h extends separately from the first end surface 11a. In other words, in the thermoelectric member 10, an end on the first end surface 11a side of at least one of the holes 10h is closed. With this configuration, the ratio of the area of the openings, in contact with the first end surface 11a, of the holes 10h forming the phononic crystal 10c to the sum of the area of the openings and the area of the first end surface 11a is likely to become small. Thus, the interfacial thermal resistance R_{U} is likely to become low, so that the performance of the thermoelectric conversion element 1b is likely to become high.

Among the holes 10h of the thermoelectric member 10, the number of the holes 10h extending separately from the first end surface 11a is not limited to a specific value. For example, 25% or more of the holes 10h of the thermoelectric member 10 on a number basis extend separately from the first end surface 11a. In the thermoelectric member 10, the ratio of the number of the holes 10h extending separately from the first end surface 11a to the number of the holes 10h of the thermoelectric member 10 may be 30% or more, 40% or more, or 50% or more. This ratio may be 60% or more, 70% or more, 80% or more, or 90% or more. In the thermoelectric member 10, all the holes 10h may extend separately from the first end surface 11a.

For example, in a case where all the holes 10h of the thermoelectric member 10 extend separately from the first end surface 11a, the interfacial thermal resistance R_{U} can be halved as compared to a thermoelectric conversion element according to the reference example described in embodiment 1.

In a case where the ratio of the number of the holes 10h extending separately from the first end surface 11a to the number of the holes 10h of the thermoelectric member 10 is 50%, the interfacial thermal resistance R_{U} can be reduced to about 0.67 times as compared to the thermoelectric conversion element according to the reference example. In a case where the ratio of the number of the holes 10h extending separately from the first end surface 11a to the number of the holes 10h of the thermoelectric member 10 is 25%, the interfacial thermal resistance R_{U} can be reduced to about 0.8 times as compared to the thermoelectric conversion element according to the reference example.

In a case where the hole 10h extends separately from the first end surface 11a, the ratio of a distance between the first end surface 11a and the hole 10h in the direction in which the hole 10h extends to the dimension of the thermoelectric member 10 in the direction in which the hole 10h extends, is not limited to a specific value. The ratio is 20% or less, for example. With this configuration, the thermal conductivity of the thermoelectric member 10 is likely to become low. This is because the thermal conductivity of the thermoelectric member 10 is expected to be reduced owing to the phononic crystal 10c in an area where the hole 10h is present in the direction in which the hole 10h extends in the thermoelectric member 10. Thus, reducing the above ratio is advantageous in terms of reduction in the thermal conductivity of the thermoelectric member 10. The above ratio may be 15% or less, 10% or less, or 5% or less.

As shown in FIG. 6, for example, in the thermoelectric member 10, ends on the second end surface 11b side of the holes 10h are opened.

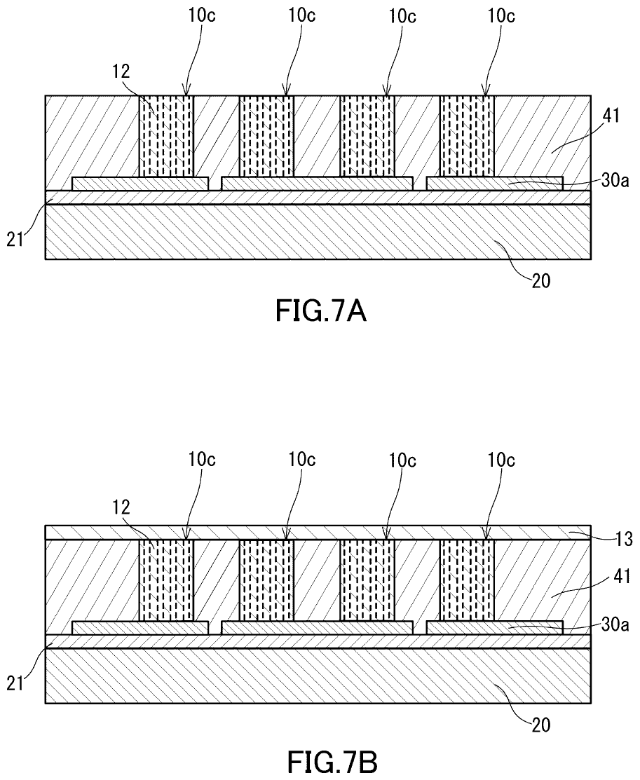

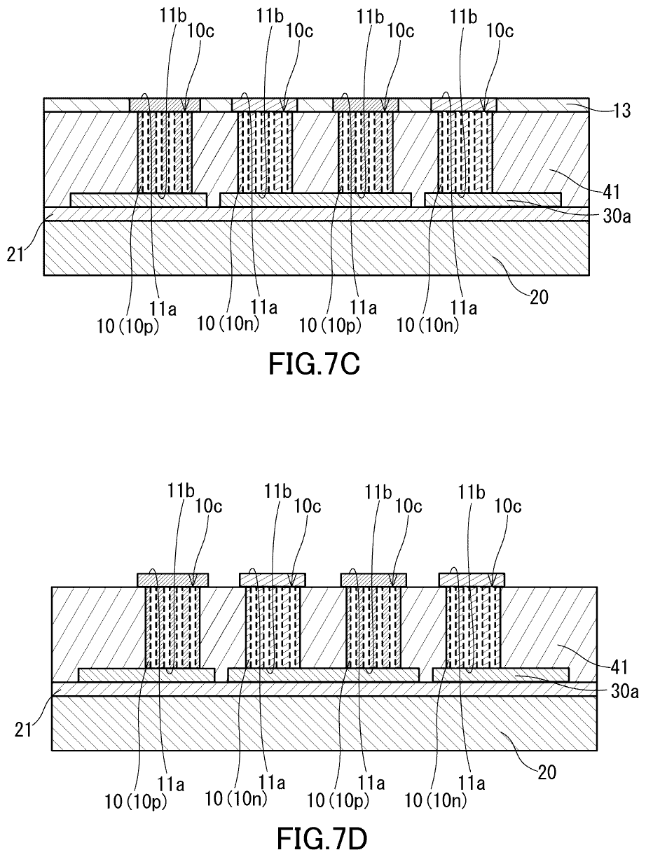

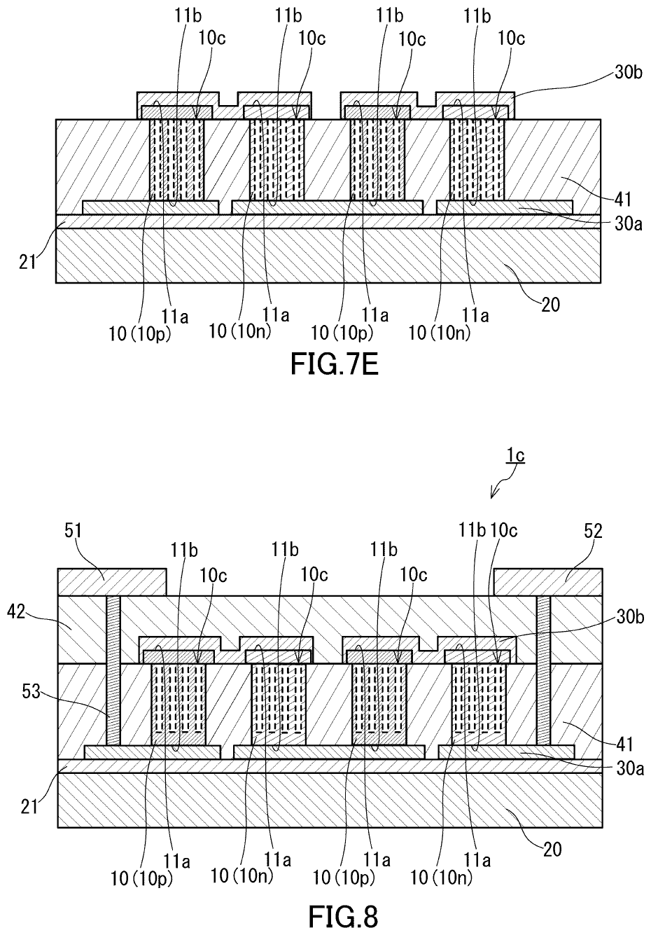

An example of a method for manufacturing the thermoelectric conversion element 1b of embodiment 2 will be described. The method for manufacturing the thermoelectric conversion element 1b is not limited to the following method. FIG. 7A to FIG. 7E show the method for manufacturing the thermoelectric conversion element 1b.

The thermoelectric conversion element 1b can be manufactured by applying the manufacturing method described in embodiment 1, for example. In the same manner as the manufacturing method in embodiment 1, the first wiring 30a and the first interlayer insulation film 41 are formed on the foundation insulation film 21 formed on the substrate 20 such as an Si substrate. Recesses 15 are formed in the first interlayer insulation film 41, the recesses 15 are filled with the thermoelectric material thin film 12, and the same structure as in FIG. 5F is formed by CMP. Then, the phononic crystals 10c are formed in the thermoelectric material thin film 12 by the same method as in embodiment 1. As shown in FIG. 7A, at this stage, both ends of the holes 10h of the phononic crystals 10c formed in the thermoelectric material thin film 12 are opened on the thermoelectric material thin film 12, and thus the holes 10h are formed as through holes.

Next, as shown in FIG. 7B, a thermoelectric material thin film 13 containing the same kind of material as the material forming the thermoelectric material thin film 12 is formed on the first interlayer insulation film 41 and the thermoelectric material thin film 12. In this case, in order to prevent the insides of the holes 10h of the phononic crystal 10c from being filled with a material forming the thermoelectric material thin film 13, a method such as oblique incidence sputtering can be used.

Next, as shown in FIG. 7C, doping is performed in predetermined areas of the thermoelectric material thin films 12 and 13, whereby the p-type thermoelectric members 10p and the n-type thermoelectric members 10n are formed. The doping can be performed by a method such as ion implantation. Then, as shown in FIG. 7D, the thermoelectric material thin film 13 in an area where doping is not performed is removed by etching. This step may be omitted in a case where the thermoelectric material thin film 13 in the area where doping is not performed has an electric insulation property.

Next, as shown in FIG. 7E, the second wiring 30b made of an electric conductor such as Al is formed. For example, a pattern to be the second wiring 30b is formed by photolithography and etching, or lift-off, from an Al film or the like formed by a method such as sputtering. Then, the second interlayer insulation film 42, the plugs 53, the first electrode pad 51, and the second electrode pad 52 are formed by the same method as for the thermoelectric conversion element 1a.

### Embodiment 3

FIG. 8 shows a thermoelectric conversion element 1c of embodiment 3. The thermoelectric conversion element 1c is configured in the same manner as the thermoelectric conversion elements 1a and 1b, except for specifically described parts. Components of the thermoelectric conversion element 1c that are the same as or correspond to those of the thermoelectric conversion element 1a are denoted by the same reference characters and the detailed description thereof is omitted. The description regarding the thermoelectric conversion elements 1a and 1b also applies to the thermoelectric conversion element 1c, unless there is technical contradiction therebetween.

As shown in FIG. 8, in the thermoelectric member 10 of the thermoelectric conversion element 1c, at least one of the holes 10h extends separately from both of the first end surface 11a and the second end surface 11b which are both end surfaces of the thermoelectric member 10 in the direction in which the hole 10h extends. In other words, in the thermoelectric member 10, both ends of at least one of the holes 10h are closed. With this configuration, both of the interfacial thermal resistance R_{B} and the interfacial thermal resistance R_{U} are likely to become low.

The number of the holes 10h extending separately from both of the first end surface 11a and the second end surface 11b is not limited to a specific value. For example, 25% or more of the holes 10h of the thermoelectric member 10 on a number basis extend separately from both of the first end surface 11a and the second end surface 11b. In the thermoelectric member 10, the ratio of the number of the holes 10h extending separately from both of the first end surface 11a and the second end surface 11b to the number of the holes 10h of the thermoelectric member 10 may be 30% or more, 40% or more, or 50% or more. This ratio may be 60% or more, 70% or more, 80% or more, or 90% or more. In the thermoelectric member 10, all the holes 10h may extend separately from the first end surface 11a.

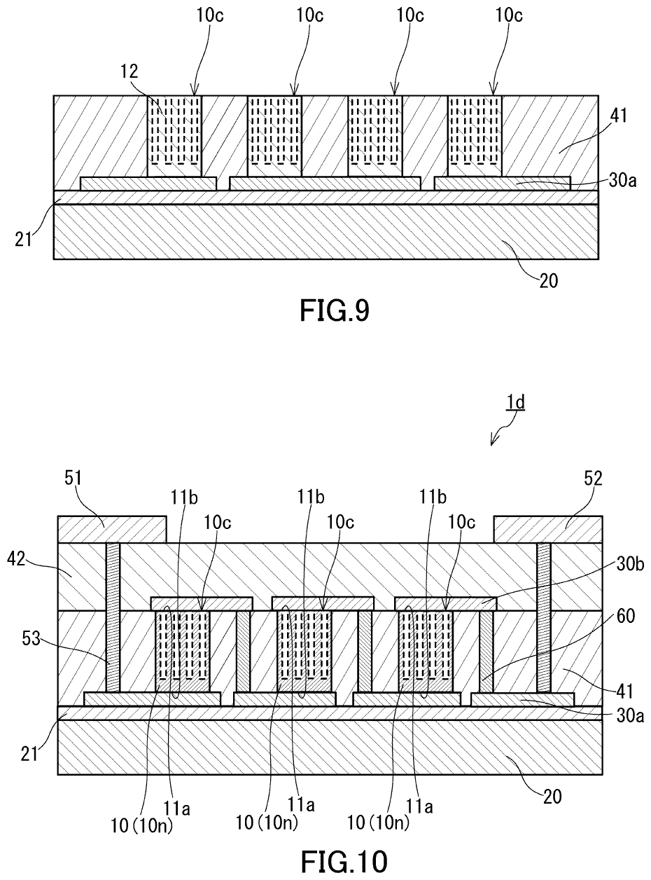

An example of a method for manufacturing the thermoelectric conversion element 1c of embodiment 3 will be described. The method for manufacturing the thermoelectric conversion element 1c is not limited to the following method. FIG. 9 shows an example of the method for manufacturing the thermoelectric conversion element 1c.

The thermoelectric conversion element 1c can be manufactured by applying the manufacturing method described in embodiment 1, for example. In the same manner as the manufacturing method in embodiment 1, the first wiring 30a and the first interlayer insulation film 41 are formed on the foundation insulation film 21 formed on the substrate 20 such as an Si substrate. Recesses 15 are formed in the first interlayer insulation film 41, the recesses 15 are filled with the thermoelectric material thin film 12, and the same structure as in FIG. 5F is formed by CMP. Then, the phononic crystals 10c are formed in the thermoelectric material thin film 12 by the same method as in embodiment 1. By adjusting the time for etching on the basis of a result of measuring the etching rate of the thermoelectric material thin film 12 in advance, the phononic crystal 10c can be formed such that the holes 10h extend separately from the second end surface 11b, as shown in FIG. 9. Then, by the same method as in embodiment 2, a thermoelectric material thin film containing the same kind of material as the material forming the thermoelectric material thin film 12 is formed on the first interlayer insulation film 41 and the phononic crystals 10c. Thus, the phononic crystal 10c in which at least one of the holes 10h extends separately from both of the first end surface 11a and the second end surface 11b is obtained. Next, after the p-type thermoelectric members 10p and the n-type thermoelectric members 10n are formed by doping, the first wiring 40a, the second interlayer insulation film 42, the plugs 53, the first electrode pad 51, and the second electrode pad 52 are formed by the same method as in embodiment 2.

### Embodiment 4

FIG. 10 shows a thermoelectric conversion element 1d of embodiment 4. The thermoelectric conversion element 1d is configured in the same manner as the thermoelectric conversion elements 1a, 1b, and 1c, except for specifically described parts. Components of the thermoelectric conversion element 1d that are the same as or correspond to those of the thermoelectric conversion element 1a are denoted by the same reference characters and the detailed description thereof is omitted. The description regarding the thermoelectric conversion elements 1a, 1b, and 1c also applies to the thermoelectric conversion element 1d, unless there is technical contradiction therebetween.

As shown in FIG. 10, the thermoelectric conversion element 1d is a uni-leg type element. The thermoelectric conversion element 1d includes the n-type thermoelectric members 10n as the thermoelectric members 10. Meanwhile, the thermoelectric conversion element 1d does not include p-type thermoelectric members. The thermoelectric conversion element 1d may be configured to include the p-type thermoelectric members 10p without including the n-type thermoelectric members 10n.

In the thermoelectric conversion element 1d, electroconductive members 60 and the n-type thermoelectric members 10b are disposed between the first wiring 30a and the second wiring 30b above the foundation insulation film 21. The electroconductive member 60 has a thickness equivalent to that of the n-type thermoelectric member 10n. The n-type thermoelectric members 10n and the electroconductive members 60 are connected electrically in series via the first wiring 30a and the second wiring 30b, and thus serve as thermocouples. In a case where the thermoelectric conversion element 1d includes a plurality of n-type thermoelectric members 10n and a plurality of electroconductive members 60, each n-type thermoelectric member 10n and each electroconductive member 60 are alternately connected electrically in series via the first wiring 30a and the second wiring 30b. In the thermoelectric conversion element 1d, the n-type thermoelectric members 10n, the electroconductive members 60, the first wiring 30a, and the second wiring 30b are covered by the first interlayer insulation film 41 and the second interlayer insulation film 42. The first electrode pad 51 and the second electrode pad 52 are electrically connected via the plugs 53, the first wiring 30a, the second wiring 30b, the n-type thermoelectric members 10n, and the electroconductive members 60. The material forming the electroconductive member 60 is not limited to a specific material. The material is desirably a metal material such as Al, Ti, W, TiN, TaN, and Cu.

In the thermoelectric conversion element 1d, the holes 10h of the phononic crystal 10c extend separately from the second end surface 11b, for example. In the thermoelectric conversion element 1d, the holes 10h may extend separately from the first end surface 11a as in the thermoelectric conversion element 1b, or may extend separately from both of the first end surface 11a and the second end surface 11b as in the thermoelectric conversion element 1c, for example.

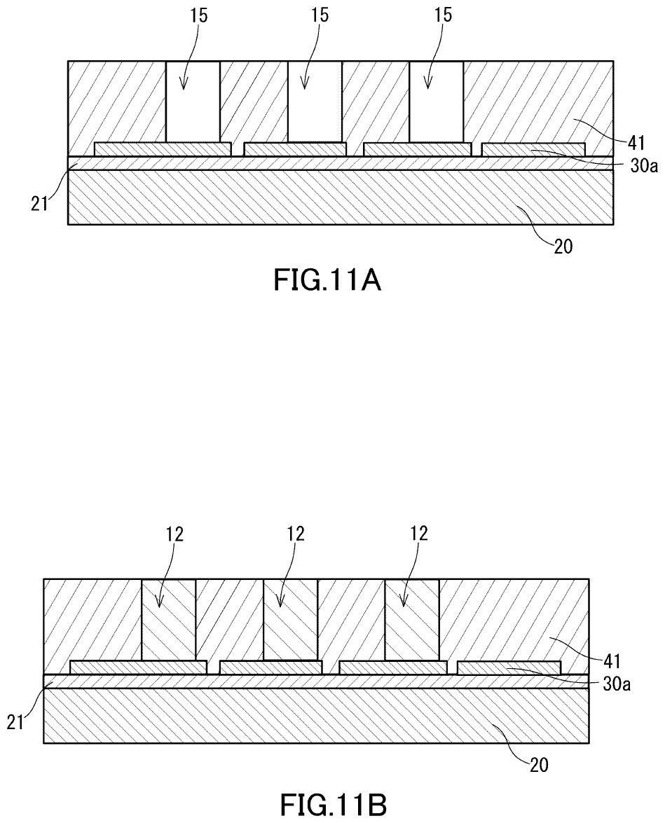

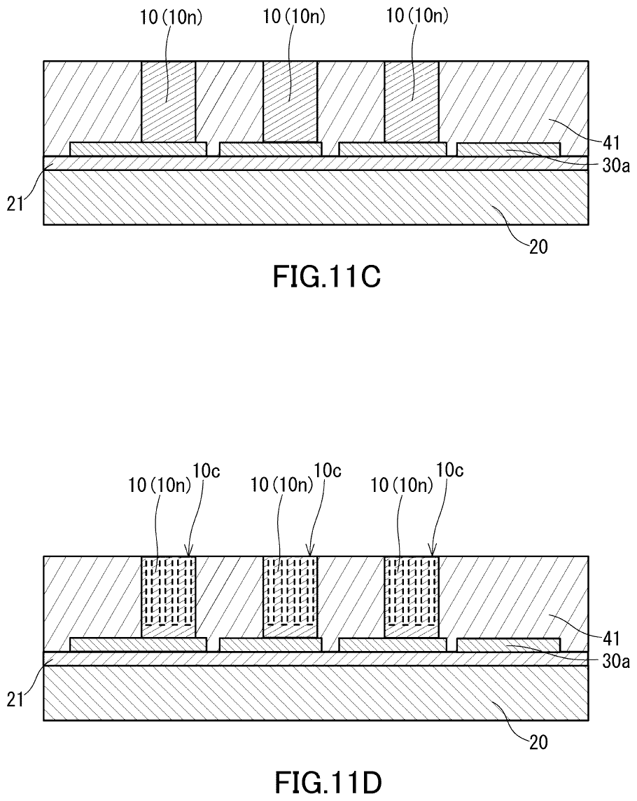

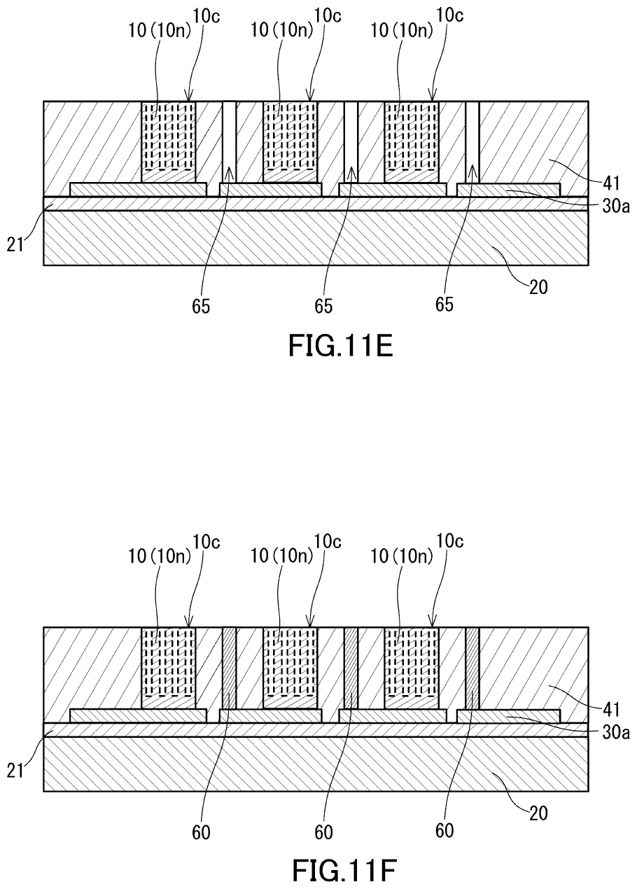

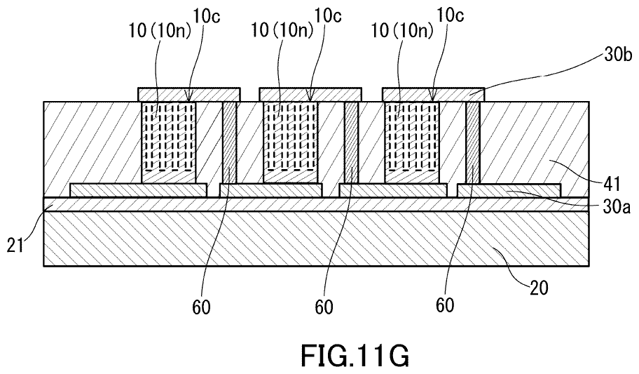

An example of a method for manufacturing the thermoelectric conversion element 1d of embodiment 4 will be described. The method for manufacturing the thermoelectric conversion element 1d is not limited to the following method. FIG. 11A to FIG. 11G show the method for manufacturing the thermoelectric conversion element 1d.

The thermoelectric conversion element 1d can be manufactured by applying the manufacturing method described in embodiment 1, for example. In the same manner as the manufacturing method in embodiment 1, the first wiring 30a and the first interlayer insulation film 41 are formed on the foundation insulation film 21 formed on the substrate 20 such as an Si substrate. As shown in FIG. 11A, recesses 15 are formed in the first interlayer insulation film 41. Then, the recesses 15 are filled with the thermoelectric material thin film 12, and an extra thermoelectric material thin film 12 is removed by CMP, whereby a structure as shown in FIG. 11B is obtained. Next, the thermoelectric material thin film 12 is doped by a method such as ion implantation, whereby the n-type thermoelectric members 10n are obtained as shown in FIG. 11C.

Next, by the same method as in embodiment 1, 2, or 3, as shown in FIG. 11D, the phononic crystals 10c each including the holes 10h separated from at least one end surface selected from the group consisting of the first end surface 11a and the second end surface 11b are formed in the thermoelectric members 10.

Next, as shown in FIG. 11E, recesses 65 are formed in the first interlayer insulation film 41 by lithography and etching. Parts of the first wiring 30a are exposed through the recesses 65. Then, as shown in FIG. 11F, a thin film of a metal material such as Al is formed in each recess 65, and an extra thin film of the metal material is removed by CMP or the like, whereby the electroconductive member 60 is obtained. Then, as shown in FIG. 11G, the second wiring 30b made of an electric conductor such as Al is formed. A pattern of the second wiring 30b is formed by photolithography and etching, or lift-off, from an Al film formed by sputtering or the like. In order to prevent the material of the second wiring 30b from entering the insides of the holes 10h of the phononic crystal 10c, a method such as oblique incidence sputtering may be used. Then, as in embodiment 1, the second interlayer insulation film 42, the metal plugs 53, the first electrode pad 51, and the second electrode pad 52 are formed. Thus, the thermoelectric conversion element 1d can be manufactured.

### Other Embodiments

As described in embodiment 1, the thermoelectric conversion element 1a may be configured so as to satisfy the condition (i). The ratio of the number of the holes 10h satisfying the condition (i) to the number of the holes 10h of the thermoelectric member 10 is, for example, 25% or more, and may be 30% or more, 40% or more, 50% or more, or 60% or more. The ratio may be 70% or more, 80% or more, or 90% or more. All the holes 10h of the thermoelectric member 10 may satisfy the condition (i).

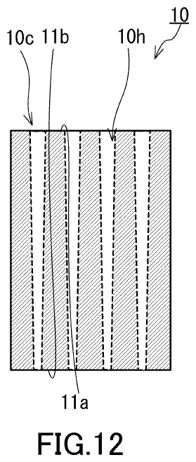

In a case where the condition (i) is satisfied, in the thermoelectric member 10, at least one of the holes 10h may be formed as a through hole. FIG. 12 is a sectional view showing another example of the thermoelectric member 10. The thermoelectric member 10 may be a p-type thermoelectric member or an n-type thermoelectric member. As shown in FIG. 12, in the thermoelectric member 10, for example, the holes 10h are through holes that are tapered. The holes 10h are tapered toward the second end surface 11b. The holes 10h may be tapered toward the first end surface 11a or may be tapered toward both end surfaces 11a and 11b. Such holes 10h can be formed through adjustment of an etching condition in manufacturing of the phononic crystal 10c.

### Additional Notes

From the above description, the following technologies are disclosed.

### (Technology 1)

A thermoelectric conversion element comprising a thermoelectric member having a phononic crystal including a plurality of holes arranged along a plane, wherein
at least one condition selected from the group consisting of the following (i) and (ii) is satisfied:
(i) an area occupied by the holes in a plan view of at least one of both end surfaces of the thermoelectric member in a direction in which the hole extends is smaller than an average value of sectional areas determined by dividing a volume of the holes by a length of the holes; and
(ii) at least one of the holes extends separately from at least one of the both end surfaces.

### (Technology 2)

The thermoelectric conversion element according to technology 1, further comprising a substrate, wherein
the thermoelectric member is disposed above the substrate,
the thermoelectric member has a first end surface, and a second end surface which is closer to the substrate than the first end surface is, in the direction in which the hole extends, and
at least one of the holes extends separately from the second end surface.

### (Technology 3)

The thermoelectric conversion element according to technology 1, wherein
25% or more of the holes on a number basis extend separately from the second end surface.

### (Technology 4)

The thermoelectric conversion element according to technology 2 or 3, wherein
a ratio of a distance between the second end surface and the hole in the direction in which the hole extends, to a dimension of the thermoelectric member in the direction in which the hole extends, is 20% or less.

### (Technology 5)

The thermoelectric conversion element according to any one of technologies 1 to 4, further comprising a substrate, wherein
the thermoelectric member is disposed above the substrate,
the thermoelectric member has a first end surface, and a second end surface which is closer to the substrate than the first end surface is, in the direction in which the hole extends, and
at least one of the holes extends separately from the first end surface.

### (Technology 6)

The thermoelectric conversion element according to technology 5, wherein
25% or more of the holes on a number basis extend separately from the first end surface.

### (Technology 7)

The thermoelectric conversion element according to technology 5 or 6, wherein
a ratio of a distance between the first end surface and the hole in the direction in which the hole extends, to a dimension of the thermoelectric member in the direction in which the hole extends, is 20% or less.

### (Technology 8)

The thermoelectric conversion element according to any one of technologies 1 to 7, wherein
at least one of the holes extends separately from the both end surfaces.

### (Technology 9)

The thermoelectric conversion element according to technology 8, wherein
25% or more of the holes on a number basis extend separately from the both end surfaces.

### INDUSTRIAL APPLICABILITY

The thermoelectric conversion element of the present disclosure is applicable to various purposes including purposes of electric generation and temperature control, for example.

1. A thermoelectric conversion element comprising a thermoelectric member having a phononic crystal including holes arranged along a plane, wherein
the holes include a hole,
a first area is occupied by the hole in a plan view of one of the end surfaces of the thermoelectric member in a direction in which the hole extends,
a second area is occupied by the hole in a plan view of the other of the end surfaces of the thermoelectric member in the direction,
at least one condition selected from the group consisting of the following (i) and (ii) is satisfied:
(i) each of the first area and the second area or either the first area or the second area is smaller than an average value of cross-sectional areas of the hole; and
(ii) at least one of the holes extends separately from at least one of the both end surfaces.

2. The thermoelectric conversion element according to claim 1, further comprising a substrate, wherein
the thermoelectric member is disposed above the substrate,
the thermoelectric member has a first end surface, and a second end surface which is closer to the substrate than the first end surface is, in the direction in which the hole extends, and
at least one of the holes extends separately from the second end surface.

3. The thermoelectric conversion element according to claim 2, wherein
25% or more of the holes on a number basis extend separately from the second end surface.

4. The thermoelectric conversion element according to claim 2, wherein
a ratio of a distance between the second end surface and the hole in the direction in which the hole extends, to a dimension of the thermoelectric member in the direction in which the hole extends, is 20% or less.

5. The thermoelectric conversion element according to claim 1, further comprising a substrate, wherein
the thermoelectric member is disposed above the substrate,
the thermoelectric member has a first end surface, and a second end surface which is closer to the substrate than the first end surface is, in the direction in which the hole extends, and
at least one of the holes extends separately from the first end surface.

6. The thermoelectric conversion element according to claim 5, wherein
25% or more of the holes on a number basis extend separately from the first end surface.

7. The thermoelectric conversion element according to claim 5, wherein
a ratio of a distance between the first end surface and the hole in the direction in which the hole extends, to a dimension of the thermoelectric member in the direction in which the hole extends, is 20% or less.

8. The thermoelectric conversion element according to claim 1, wherein
at least one of the holes extends separately from the both end surfaces.

9. The thermoelectric conversion element according to claim 8, wherein
25% or more of the holes on a number basis extend separately from the both end surfaces.

10. The thermoelectric conversion element according to claim 1, wherein
the average value of the cross-sectional areas of the hole is determined by dividing a volume of an inside of the hole by a length that is a dimension of the hole in the direction.
